(19) United States
(12) Patent Application Publication
(10) Pub. No.: US 2009/0288703 A1
(43) Pub. Date: Nov. 26, 2009

(54) Wide Band Gap Window Layers In Inverted Metamorphic Multijunction Solar Cells

(75) Inventors: Mark A. Stan, Albuquerque, NM (US); Arthur Cornfeld, Sandia Park, NM (US); Benjamin Cho, Albuquerque, NM (US)

Correspondence Address: EMCORE CORPORATION, 1600 EUBANK BLVD, S.E., ALBUQUERQUE, NM, 87123, US

(73) Assignee: Emcore Corporation, Albuquerque, NM (US)

(21) Appl. No.: 12/123,864

(22) Filed: May 20, 2008

(51) Int. Cl. H01L 31/0336; H01L 31/18

(52) U.S. Cl. 136/255; 438/87; 257/E31.005

(57) ABSTRACT

A method of forming a multijunction solar cell including an upper subcell, a middle subcell, and a lower subcell, the method including: providing a substrate for the epitaxial growth of semiconductor material; forming a first solar subcell on the substrate having a first band gap and including a pseudomorphic window layer; forming a second solar subcell over the first solar subcell having a second band gap smaller than the first band gap; forming a graded interlayer over the second subcell, the graded interlayer having a third band gap greater than the second band gap; and forming a third solar subcell over the graded interlayer having a fourth band gap smaller than the second band gap such that the third subcell is lattice mismatched with respect to the second solar subcell.

### REFERENCE TO RELATED APPLICATIONS

This application is related to co-pending U.S. patent application Ser. No. 12/102,550 filed Apr. 15, 2008.

This application is related to co-pending U.S. patent application Ser. No. 12/047,842, and U.S. Ser. No. 12/047,944, filed Mar. 13, 2008.

This application is also related to co-pending U.S. patent applicant Ser. No. 11/860,183 filed Sep. 24, 2007.

This application is also related to co-pending U.S. patent application Ser. No. 12/023,772, filed Jan. 31, 2008.

This application is also related to co-pending U.S. patent application Ser. No. 11/956,069, filed Dec. 13, 2007.

This application is also related to co-pending U.S. patent application Ser. No. 11/860,142 filed Sep. 24, 2007.

This application is also related to co-pending U.S. patent application Ser. No. 11/836,402 filed Aug. 8, 2007.

This application is also related to co-pending U.S. patent application Ser. No. 11/616,596 filed Dec. 27, 2006.

This application is also related to co-pending U.S. patent application Ser. No. 11/614,332 filed Dec. 21, 2006.

This application is also related to co-pending U.S. patent application Ser. No. 11/445,793 filed Jun. 2, 2006.

This application is also related to co-pending U.S. patent application Ser. No. 11/500,053 filed Aug. 7, 2006.

### GOVERNMENT RIGHTS STATEMENT

This invention was made with government support under Contract No. FA9453-06-C-0345 awarded by the U.S. Air Force. The Government has certain rights in the invention.

### BACKGROUND OF THE INVENTION

1. Field of the Invention

The present invention relates to the field of solar cell semiconductor devices, and to multijunction solar cells based on III-V semiconductor compounds including a metamorphic layer. More particularly, the invention relates to fabrication processes and devices also known as inverted metamorphic multifunction solar cells.

2. Description of the Related Art

Photovoltaic cells, also called solar cells, are one of the most important new energy sources that have become available in the past several years. Considerable effort has gone into solar cell development. As a result, solar cells are currently being used in a number of commercial and consumer-oriented applications. While significant progress has been made in this area, the requirement for solar cells to meet the needs of more sophisticated applications has not kept pace with demand. Applications such as concentrator terrestrial power systems and satellites used in data communications have dramatically increased the demand for solar cells with improved power and energy conversion characteristics.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as the payloads become more sophisticated, solar cells, which act as the power conversion devices for the on-board power systems, become increasingly more important.

Solar cells are often fabricated in vertical, multijunction structures, and disposed in horizontal arrays, with the individual solar cells connected together in a series. The shape and structure of an array, as well as the number of cells it contains, are determined in part by the desired output voltage and current.

Inverted metamorphic solar cell structures such as described in M. W. Wanlass et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005) present an important conceptual starting point for the development of future commercial high efficiency solar cells. The structures described in such reference present a number of practical difficulties relating to the appropriate choice of materials and fabrication steps, in particular associated with the lattice mismatched layers between the “lower” subcell (the subcell with the lowest band gap) and the adjacent subcell.

Prior to the present invention, the materials and fabrication steps disclosed in the prior art have not been adequate to produce a commercially viable and energy efficient solar cell using commercially established fabrication processes for producing an inverted metamorphic multijunction cell structure.

### SUMMARY OF THE INVENTION

Briefly, and in general terms, the present invention provides a method of forming a multifunction solar cell comprising an upper subcell, a middle subcell, and a lower subcell, the method comprising providing first substrate for the epitaxial growth of semiconductor material; forming a first solar subcell on the substrate having a first band gap; the cell including a base layer and an emitter layer, and a window layer adjacent to said emitter layer and lattice mismatched thereto, having a lattice constant which differs from the lattice constant of the emitter layer by less than approximately 0.9%; forming a second subcell over the first subcell having a second band gap smaller than the first band gap; forming a grading interlayer over the second solar subcell, the grading interlayer having a third band gap greater than the second band gap; and forming a third subcell over the grading interlayer having a fourth band gap smaller than the second band gap such that the third subcell is lattice mismatched with respect to the second subcell.

In another aspect, the present invention provides a method of manufacturing a solar cell comprising providing a first semiconductor substrate; depositing on the first substrate a sequence of layers of semiconductor material forming a solar cell, including a window layer with a bandgap of more than 2.25 eV; mounting a surrogate second substrate on top of the sequence of layers; and removing the first substrate.

In another aspect, the present invention provides a multifunction solar cell comprising a substrate; a first solar subcell on the substrate having a first band gap; a pseudomorphic window layer disposed over the first subcell having a bandgap greater than that of a lattice matched window layer; a second solar subcell disposed over the first subcell and having a second band gap smaller than the first band gap; a grading interlayer disposed over the barrier layer and having a third band gap greater than the second band gap; and a third solar subcell disposed over the grading interlayer that is lattice mismatched with respect to the middle subcell and having a fourth band gap smaller than the third band gap.

In another aspect, the present invention provides A method for increasing current generation in a photovoltaic cell or other optoelectronic device comprising providing a subcell an emitter layer having a first lattice constant; growing a lattice-mismatched window layer positioned directly adjacent to said emitter layer composed of a material, having a second lattice constant different from the first lattice constant material lattice constant and said second material lattice constant differ in material lattice constant values by at least less than approximately 1.0%, wherein said lattice mismatched window layer is fully strained window layer.

### BRIEF DESCRIPTION OF THE DRAWINGS

The invention will be better and more fully appreciated by reference to the following detailed description when considered in conjunction with the accompanying drawings, wherein:

FIG. 1 is a graph representing the bandgap of certain binary materials and their lattice constants;

FIG. 2 is a cross-sectional view of the solar cell of the invention after the deposition of semiconductor layers on the growth substrate;

FIG. 3 is a cross-sectional view of the solar cell of FIG. 2 after the next process step;

FIG. 4 is a cross-sectional view of the solar cell of FIG. 3 after next process step;

FIG. 5A is a cross-sectional view of the solar cell of FIG. 4 after the next process step in which a surrogate substrate is attached;

FIG. 5B is a cross-sectional view of the solar cell of FIG. 5A after the next process step in which the original substrate is removed;

FIG. 5C is another cross-sectional view of the solar cell of FIG. 5B with the surrogate substrate on the bottom of the Figure;

FIG. 6 is a simplified cross-sectional view of the solar cell of FIG. 5C after the next process step;

FIG. 7 is a cross-sectional view of the solar cell of FIG. 6 after the next process step;

FIG. 8 is a cross-sectional view of the solar cell of FIG. 7 after the next process step;

FIG. 9 is a cross-sectional view of the solar cell of FIG. 8 after the next process step;

FIG. 10A is a top plan view of a wafer in which the solar cells are fabricated;

FIG. 10B is a bottom plan view of a wafer in which the solar cells are fabricated;

FIG. 11 is a cross-sectional view of the solar cell of FIG. 9 after the next process step;

FIG. 12 is a cross-sectional view of the solar cell of FIG. 11 after the next process step;

FIG. 13 is a top plan view of the wafer of FIG. 12 after the next process step in which a trench is etched around the cell;

FIG. 14A is a cross-sectional view of the solar cell of FIG. 12 after the next process step in a first embodiment of the present invention;

FIG. 14B is a cross-sectional view of the solar cell of FIG. 14A after the next process step in a second embodiment of the present invention;

FIG. 15 is a cross-sectional view of the solar cell of FIG. 14B after the next process step in a third embodiment of the present invention

FIG. 16 is a graph of the doping profile in a base layer in the metamorphic solar cell according to the present invention;

FIG. 17 is an external quantum efficiency (EQE) graph of an inverted metamorphic solar cell with a window layer as known in the prior art; and

FIG. 18 is an external quantum efficiency (EQE) graph of inverted metamorphic solar cell with the high band gap window layer according to the present invention, compared to the solar cell of FIG. 17.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

The basic concept of fabricating an inverted metamorphic multifunction (IMM) solar cell is to grow the subcells of the solar cell on a substrate in a “reverse” sequence. That is, the high band gap subcells (i.e. subcells with band gaps in the range of 1.8 to 2.1 eV), which would normally be the “top” subcells facing the solar radiation, are grown epitaxially on a semiconductor growth substrate, such as for example GaAs or Ge, and such subcells are therefore lattice-matched to such substrate. One or more lower band gap middle subcells (i.e. with band gaps in the range of 1.2 to 1.8 eV) can then be grown on the high band gap subcells.

At least one lower subcell is formed over the middle subcell such that the at least one lower subcell is substantially lattice-mismatched with respect to the growth substrate and such that the at least one lower subcell has a third lower band gap (i.e. a band gap in the range of 0.7 to 1.2 eV). A surrogate substrate or support structure is provided over the “bottom” or substantially lattice-mismatched lower subcell, and the growth semiconductor substrate is subsequently removed. (The growth substrate may then subsequently be re-used for the growth of a second and subsequent solar cells).

One aspect of the design of an IMM structure is to provide subcells with more optimized band gaps to increase the overall operating efficiency of multifunction solar cells. A constraint imposed in the past has been that all subcells were required to be composed of alloys with the same lattice constant. This constraint was imposed to optimize material quality. However, to optimize cell efficiency consistent with model predictions, this constraint must be relaxed and the material quality must be maintained. The role of a metamorphic buffer layer in new solar cell structures is to (1) achieve a lattice constant transition between subcells with a different lattice constant; and (2) maintain the material quality of the active subcell layers. The latter requirement normally means minimizing the density of threading dislocations in the active regions of the cell. A requisite to minimize threading dislocation creation is to maintain two-dimensional as opposed to three-dimensional growth. This condition may be influenced by several growth conditions: for example, growth temperature, grading rate, V to III ratio, template off-cut, alloy and surfactant assisted growth. The subject of related U.S. patent application Ser. No. 12/047,842 is the surfactant assisted growth of the metamorphic layer, and the subject of U.S. patent application Ser. No. 12/102,550 is the surfactant assisted growth of the barrier layers. The surfactants may be either isoelectronic atoms such as antimony (Sb) or bismuth (Bi), or non-isoelectronic or donor atoms such as selenium (Se) or tellurium (Te).

Another aspect of the design of an IMM structure, as taught in the present invention, is to increase short circuit current density (J_{SC}) in the top two subcells of the structure. One means to achieve this goal is to reduce both photon absorption in the top subcell window and carrier recombination at the interface between the emitter and window of the top cell. The increase in J_{SC} can be shared between the two top subcells by adjusting the top subcell thickness. Reduced photon absorption and interface recombination will occur for increased band gap materials. AIInP exhibits the highest indirect band gap for all arsenide and phosphide based III-V compounds lattice matched to GaAs.

According to the present invention, a top cell window with increased band gap was recently incorporated in a conventional IMM structure such as described in the related patent applications of the assignee. The lattice matched AIInP window in such structures was replaced by a tensile strained AIInP window with a greater aluminum mole fraction for the purpose of increasing the window's band gap. The Al mole fraction was increased by either 1) a constant value, 2) ramped over the thickness of the window layer to an increased value, or 3) ramped over a portion of the thickness of the window layer to an increased value and then maintained at that end point value over the remaining layer. The total thickness of the window was constrained to maintain the pseudomorphic nature (i.e., the strained, or un-relaxed) of the layer. The purpose of this change was to reduce optical absorption of high energy photons in the window. As will be noted below Light I-V data indicated that an increase of 0.9 mA/cm² current equivalent photons was collected in the top cell by increasing the window band gap.

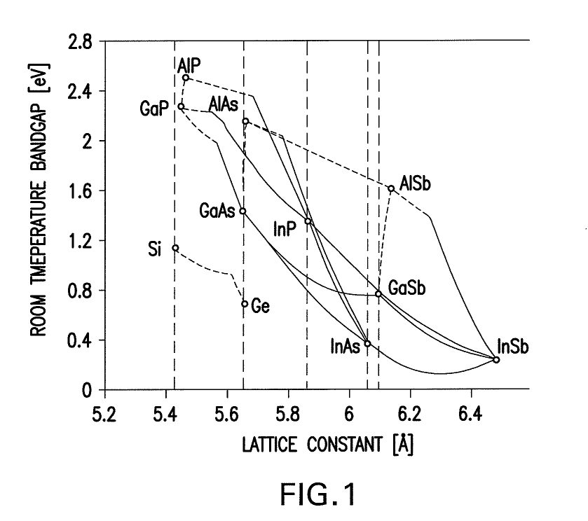

FIG. 1 is a graph representing the band gap of certain binary materials and their lattice constants. The band gap and lattice constants of ternary materials are located on the lines drawn between typical associated binary materials (such as GaAlAs being between the GaAs and AlAs points on the graph, with the band gap varying between 1.42 eV for GaAs and 2.16 eV for AlAs). Thus, depending upon the desired band gap, the material constituents of ternary materials can be appropriately selected for growth.

The lattice constants and electrical properties of the layers in the semiconductor structure are preferably controlled by specification of appropriate reactor growth temperatures and times, and by use of appropriate chemical composition and dopants. The use of a vapor deposition method, such as Organo Metallic Vapor Phase Epitaxy (OMVPE), Metal Organic Chemical Vapor Deposition (MOCVD), Molecular Beam Epitaxy (MBE), or other vapor deposition methods for the reverse growth may enable the layers in the monolithic semiconductor structure forming the cell to be grown with the required thickness, elemental composition, dopant concentration and grading and conductivity type.

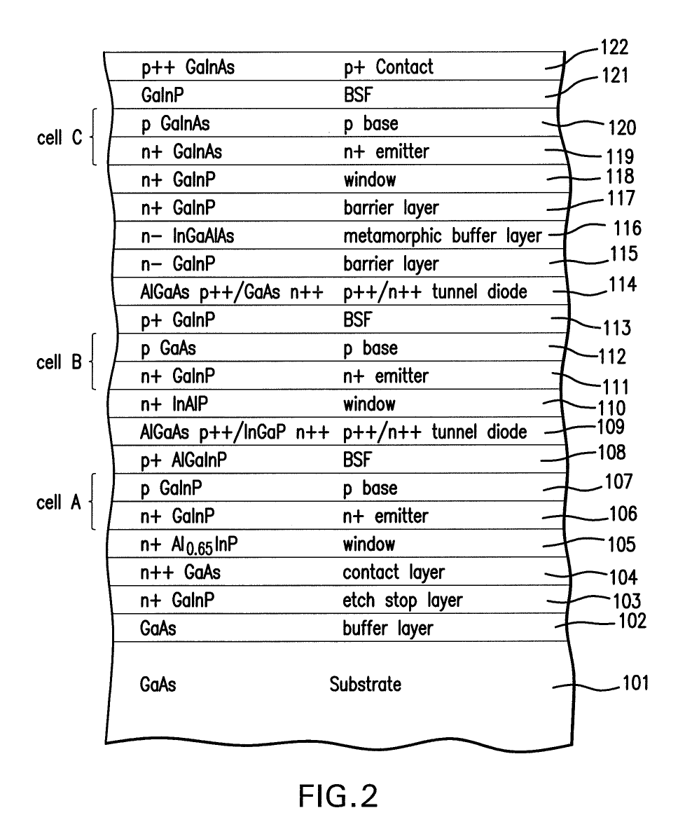

FIG. 2 depicts the multijunction solar cell according to the present invention after the sequential formation of the three subcells A, B and C on a GaAs growth substrate. More particularly, there is shown a substrate 101, which is preferably gallium arsenide (GaAs), but may also be germanium (Ge) or other suitable material. For GaAs, the substrate is preferably a 15° off-cut substrate, that is to say, its surface is orientated 15° off the (100) plane towards the (111)A plane, as more fully described in U.S. patent application Ser. No. 12/047,944, filed Mar. 13, 2008.

In the case of a Ge substrate, a nucleation layer (not shown) is deposited directly on the substrate 101. On the substrate, or over the nucleation layer (in the case of a Ge substrate), a buffer layer 102 and an etch stop layer 103 are further deposited. In the case of GaAs substrate, the buffer layer 102 is preferably GaAs. In the case of Ge substrate, the buffer layer 102 is preferably InGaAs. A contact layer 104 of GaAs is then deposited on layer 103, and a window layer 105 of Al_{0.65}InP is deposited on the contact layer. The subcell A, consisting of an n+ emitter layer 106 and a p-type base layer 107, is then epitaxially deposited on the window layer 105. The subcell A is generally latticed matched to the growth substrate 101.

The present invention provides a window layer 105 which has a greater Al mole fraction content compared with the lattice matched AlInP window layers used in the prior art, which increases the window layer's band gap. More particularly, the use of a Al_{0.65}InP window layer 105 (compared to the use of a lattice matched Al_{0.53}InP window layer provides a band gap of 2.252 eV, compared with 2.198 eV.

The use of a wide band gap Al_{0.65}InP window layer 105 results in the layer 105 being lattice mismatched with respect to the emitter layer 106, or pseudomorphic. The thickness of the layer is appropriately selected to retain the tensilely strained or unrelaxed nature of the layer. Although the mole fraction of 0.65 is preferred for achieving the desired band gap, those skilled in the art will recognize that mole fractions from approximately 0.60 to 0.70 (i.e., Al_{0.60}InP to Al_{0.70}InP) or thereabout, under suitable selection of other parameters, will be within the scope of the present invention.

It should be noted that the multijunction solar cell structure could be formed by any suitable combination of group III to V elements listed in the periodic table subject to lattice constant and bandgap requirements, wherein the group III includes boron (B), aluminum (Al), gallium (Ga), indium (In), and thallium (Tl). The group IV includes carbon (C), silicon (Si), germanium (Ge), and tin (Sn). The group V includes nitrogen (N), phosphorous (P), arsenic (As), antimony (Sb), and bismuth (Bi).

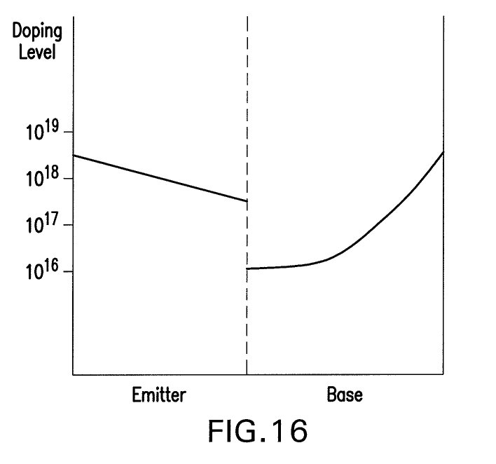

In the preferred embodiment, the emitter layer 106 is composed of InGa(Al)P and the base layer 107 is composed of InGa(Al)P. The aluminum or Al term in parenthesis in the preceding formula means that Al is an optional constituent, and in this instance may be used in an amount ranging from 0% to 30%. The doping profile of the emitter and base layers 106 and 107 will be discussed in conjunction with FIG. 16.

Subcell A will ultimately become the “top” subcell of the inverted metamorphic structure after completion of the process steps according to the present invention to be described hereinafter.

On top of the base layer 107 a back surface field (“BSF”) layer 108 is deposited and used to reduce recombination loss, preferably p+AlGaInP.

The BSF layer 108 drives minority carriers from the region near the base/BSF interface surface to minimize the effect of recombination loss. In other words, a BSF layer 18 reduces recombination loss at the backside of the solar subcell A and thereby reduces the recombination in the base.

On top of the BSF layer 108 is deposited a sequence of heavily doped p-type and n-type layers 109 which forms a tunnel diode which is an ohmic circuit element to connect subcell A to subcell B. These layers are preferably composed of p++AlGaAs, and n++InGaP.

On top of the tunnel diode layers 109 a window layer 110 is deposited, preferably n+InAlP. The window layer 110 used in the subcell B operates to reduce the interface recombination loss. It should be apparent to one skilled in the art, that additional layer(s) may be added or deleted in the cell structure without departing from the scope of the present invention.

On top of the window layer 110 the layers of subcell B are deposited: the n-type emitter layer 111 and the p-type base layer 112. These layers are preferably composed of InGaP and In_{0.015}GaAs respectively (for a Ge substrate or growth template), or InGaP and GaAs respectively (for a GaAs substrate), although any other suitable materials consistent with lattice constant and bandgap requirements may be used as well. Thus, subcell B may be composed of a GaAs, GaInP, GaInAs, GaAsSb, or GaInAsN emitter region and a GaAs, GaInAs, GaAsSb, or GaInAsN base region. The doping profile of layers 111 and 112 according to the present invention will be discussed in conjunction with FIG. 16.

In the preferred embodiment of the present invention, the middle subcell emitter has a band gap equal to the top subcell emitter, and the bottom subcell emitter has a band gap greater than the band gap of the base of the middle subcell. Therefore, after fabrication of the solar cell, and implementation and operation, neither the middle subcell B nor the bottom subcell C emitters will be exposed to absorbable radiation. Substantially radiation will be absorbed in the bases of cells B and C, which have narrower band gaps then the emitters. Therefore, the advantages of using heterojunction subcells are: 1) the short wavelength response for both subcells will improve, and 2) the bulk of the radiation is more effectively absorbed and collected in the narrower band gap base. The effect will be to increase J_{SC}.

On top of the cell B is deposited a BSF layer 113 which performs the same function as the BSF layer 109. A p++/n++ tunnel diode 114 is deposited over the BSF layer 113 similar to the layers 109, again forming an ohmic circuit element to connect subcell B to subcell C. These layers 114 are preferably compound of p++AlGaAs and n++GaAs.

A barrier layer 115, preferably composed of n-type InGa(Al)P, is deposited over the tunnel diode 114, to a thickness of about 1.0 micron. Such barrier layer is intended to prevent threading dislocations from propagating, either opposite to the direction of growth into the middle and top subcells B and C, or in the direction of growth into the bottom subcell A, and is more particularly described in copending U.S. patent application Ser. No. 11/860,183, filed Sep. 24, 2007.

In the surfactant assisted growth of the barrier layer 115 according to the present invention, a suitable chemical element is introduced into the reactor during the growth of layer 115 to improve the surface characteristics of the layer. In the preferred embodiment, such element may be an isoelectronic surfactant such as bismuth (Bi) or antimony (Sb). Although Bi or Sb are the preferred atoms, other non-isoelectronic surfactants which act as dopant or donor atoms may be used as well.

Surfactant assisted growth results in a much smoother or planarized surface. Since the surface topography affects the bulk properties of the semiconductor material as it grows and the layer becomes thicker, the use of the surfactants according to the present invention minimizes threading dislocations in the active regions, and therefore improves overall solar cell efficiency.

The term “isoelectronic” refers to surfactants such as antimony (Sb) or bismuth (Bi), since such elements have the same number of valence electrons as the P of InGaP, or as in InGaAlP, in the barrier layer. Such Sb or Bi surfactants will not typically be incorporated into the barrier layer 115.

A metamorphic layer (or graded interlayer) 116 is deposited over the barrier layer 115. Layer 116 is preferably a compositionally step-graded series of InGaAlAs layers, preferably with monotonically changing lattice constant, so as to achieve a gradual transition in lattice constant in the semiconductor structure from subcell B to subcell C while minimizing threading dislocations from occurring. The bandgap of layer 116 is constant throughout its thickness preferably approximately 1.5 eV or otherwise consistent with a value slightly greater than the bandgap of the middle subcell B. The preferred embodiment of the graded interlayer may also be expressed as being composed of (InₓGa₁₋ₓ)_{y}Al_{1-y}As, with x and y selected such that the band gap of the interlayer remains constant at approximately 1.50 eV.

In an alternative embodiment where the solar cell has only two subcells, and the “middle” cell B is the uppermost or top subcell in the final solar cell, wherein the “top” subcell B would typically have a bandgap of 1.8 to 1.9 eV, then the band gap of the interlayer would remain constant at 1.9 eV.

In the inverted metamorphic structure described in the Wanlass et al. paper cited above, the metamorphic layer consists of nine compositionally graded InGaP steps, with each step layer having a thickness of 0.25 micron. As a result, each layer of Wanlass et al. has a different bandgap. In the preferred embodiment of the present invention, the layer 116 is composed of a plurality of layers of InGaAlAs, with monotonically changing lattice constant, each layer having the same bandgap, approximately 1.5 eV.

The advantage of utilizing a constant bandgap material such as InGaAlAs is that arsenide-based semiconductor material is much easier to process in standard commercial MOCVD reactors, while the small amount of aluminum assures radiation transparency of the metamorphic layers.

Although the preferred embodiment of the present invention utilizes a plurality of layers of InGaAlAs for the metamorphic layer 116 for reasons of manufacturability and radiation transparency, other embodiments of the present invention may utilize different material systems to achieve a change in lattice constant from subcell B to subcell C. Thus, the system of Wanlass using compositionally graded InGaP is a second embodiment of the present invention. Other embodiments of the present invention may utilize continuously graded, as opposed to step graded, materials. More generally, the graded interlayer may be composed of any of the As, P, N, Sb based III-V compound semiconductors subject to the constraints of having the in-plane lattice parameter greater or equal to that of the second solar cell and less than or equal to that of the third solar cell, and having a bandgap energy greater than that of the second solar cell.

In another embodiment of the present invention, an optional second barrier layer 117 may be deposited over the InGaAlAs metamorphic layer 116. The second barrier layer 117 will typically have a different composition than that of barrier layer 115, and performs essentially the same function of preventing threading dislocations from propagating. In the preferred embodiment, barrier layer 117 is n+ type GaInP. Similar to the process described in connection with barrier layer 115, a surfactant may be used during the growth of such layer. In the preferred embodiment, such element may be an isoelectronic atom such as bismuth (Bi) or antimony (Sb). Although Bi or Sb is the preferred surfactants, other non-isoelectronic surfactants may be used as well.

A window layer 118 preferably composed of n+ type GaInP is then deposited over the barrier layer 117 (or directly over layer 116, in the absence of a second barrier layer). This window layer operates to reduce the recombination loss in subcell “C”. It should be apparent to one skilled in the art that additional layers may be added or deleted in the cell structure without departing from the scope of the present invention.

On top of the window layer 118, the layers of cell C are deposited: the n-emitter layer 119, and the p-type base layer 120. These layers are preferably composed of n type InGaAs and p type InGaAs respectively, or n type InGaP and p type InGaAs for a heterojunction subcell, although another suitable materials consistent with lattice constant and bandgap requirements may be used as well. The doping profile of layers 119 and 120 will be discussed in connection with FIG. 16.

A BSF layer 121, preferably composed of InGaP or AlGaInAs, is then deposited on top of the cell C, the BSF layer performing the same function as the BSF layers 108 and 113.

Finally a p++ contact layer 122 composed of GaInAs is deposited on the BSF layer 121.

It should be apparent to one skilled in the art, that additional layer(s) may be added or deleted in the cell structure without departing from the scope of the present invention.

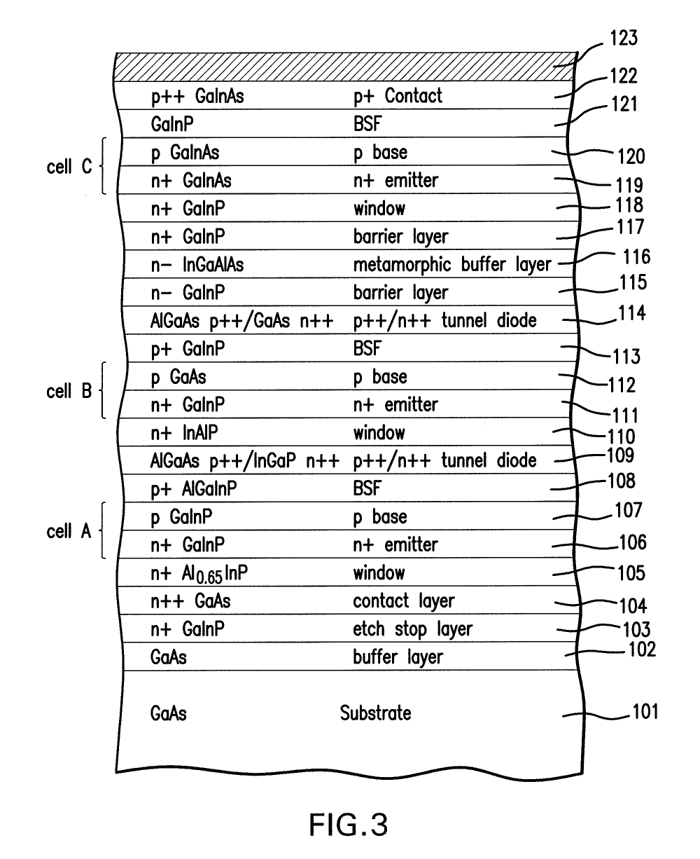

FIG. 3 is a cross-sectional view of the solar cell of FIG. 2 after the next process step in which a metal contact layer 123 is deposited over the p+ semiconductor contact layer 122. The metal is preferably the sequence of metal layers Ti/Au/Ag/Au.

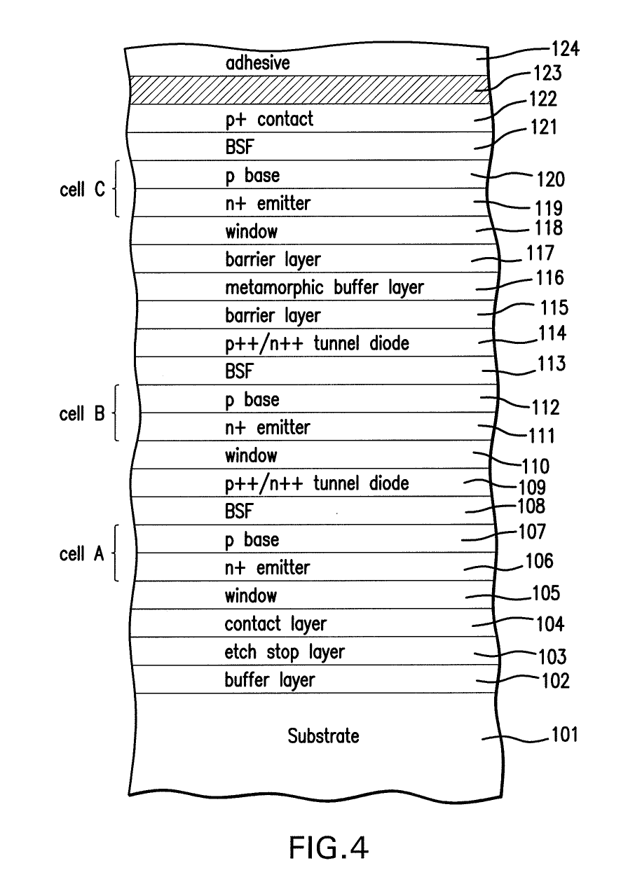

FIG. 4 is a cross-sectional view of the solar cell of FIG. 3 after the next process step in which an adhesive layer 124 is deposited over the metal layer 123. The adhesive is preferably Wafer Bond (manufactured by Brewer Science, Inc. of Rolla, Mo.).

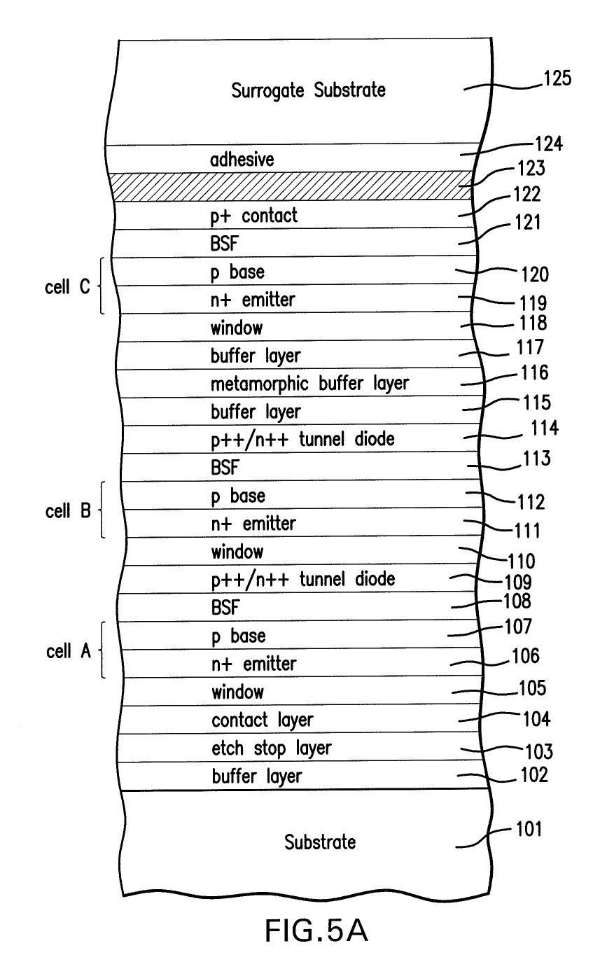

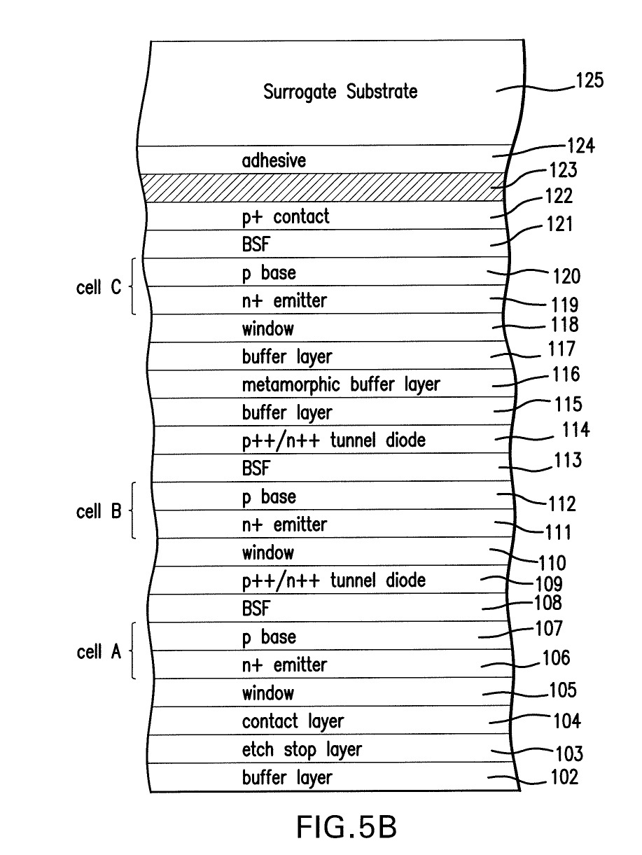

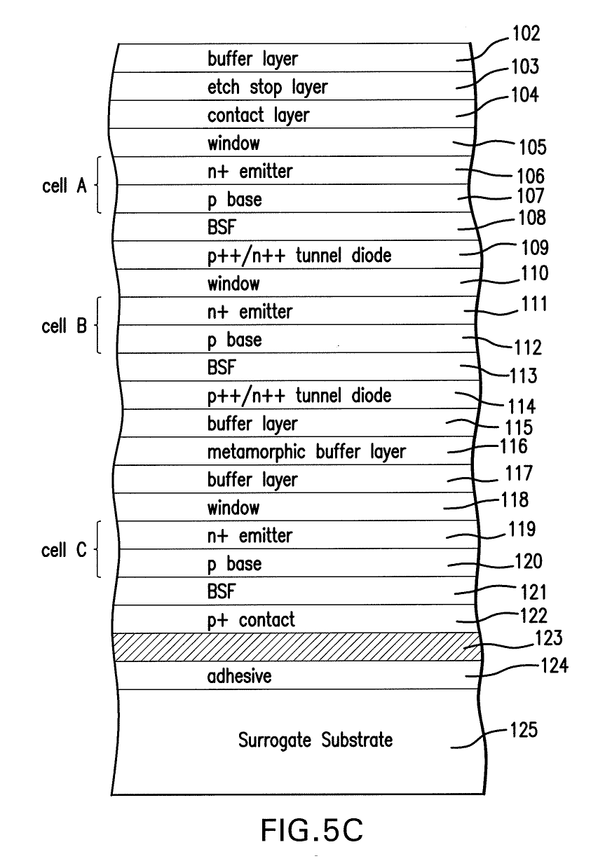

FIG. 5A is a cross-sectional view of the solar cell of FIG. 4 after the next process step in which a surrogate substrate 125, preferably sapphire, is attached. Alternative, the surrogate substrate may be GaAs, Ge or Si, or other suitable material. The surrogate substrate is about 40 mils in thickness, and is perforated with holes about 1 mm in diameter, spaced 4 mm apart, to aid in subsequent removal of the adhesive and the substrate. As an alternative to using an adhesive layer 124, a suitable substrate (e.g., GaAs) may be eutectically bonded to the metal layer 123.

FIG. 5B is a cross-sectional view of the solar cell of FIG. 5A after the next process step in which the original substrate is removed by a sequence of lapping and/or etching steps in which the substrate 101, and the buffer layer 103 are removed. The choice of a particular etchant is growth substrate dependent.

FIG. 5C is a cross-sectional view of the solar cell of FIG. 5B with the orientation with the surrogate substrate 125 being at the bottom of the Figure. Subsequent Figures in this application will assume such orientation.

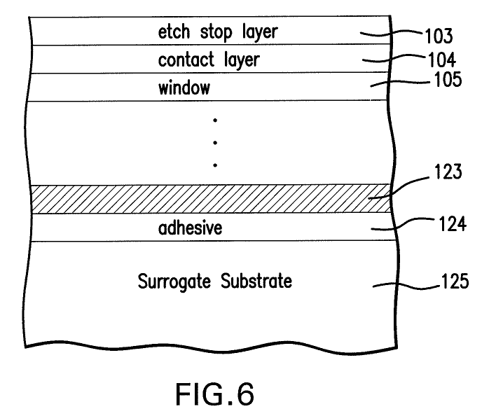

FIG. 6 is a simplified cross-sectional view of the solar cell of FIG. 5B depicting just a few of the top layers and lower layers over the surrogate substrate 125.

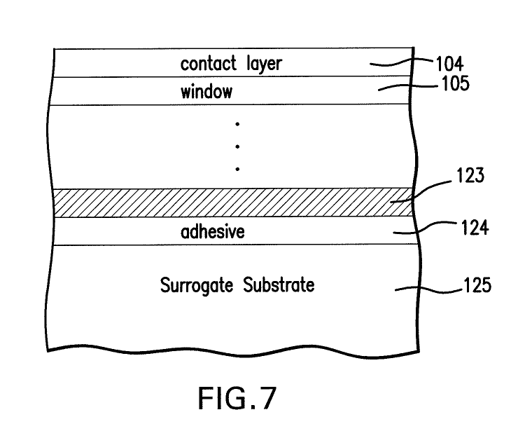

FIG. 7 is a cross-sectional view of the solar cell of FIG. 6 after the next process step in which the etch stop layer 103 is removed by a HCl/H₂O solution.

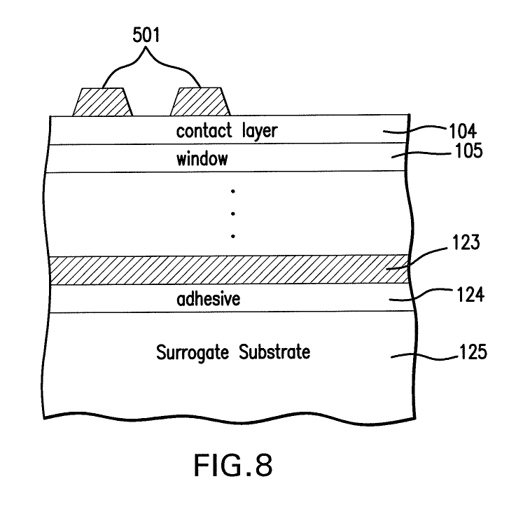

FIG. 8 is a cross-sectional view of the solar cell of FIG. 7 after the next sequence of process steps in which a photoresist mask (not shown) is placed over the contact layer 104 to form the grid lines 501. The grid lines 501 are deposited via evaporation and lithographically patterned and deposited over the contact layer 104. The mask is lifted off to form the metal grid lines 501.

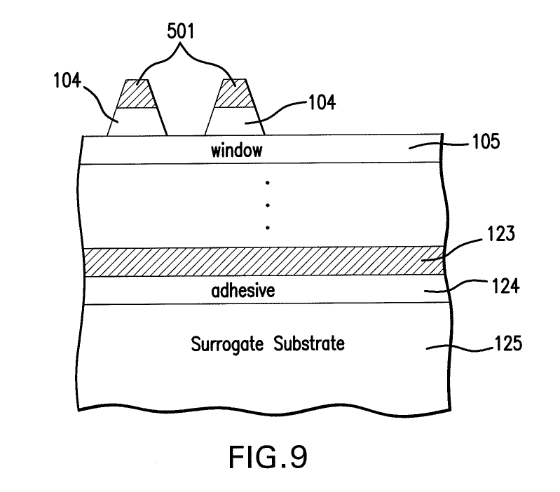

FIG. 9 is a cross-sectional view of the solar cell of FIG. 8 after the next process step in which the grid lines are used as a mask to etch down the surface to the window layer 105 using a citric acid/peroxide etching mixture.

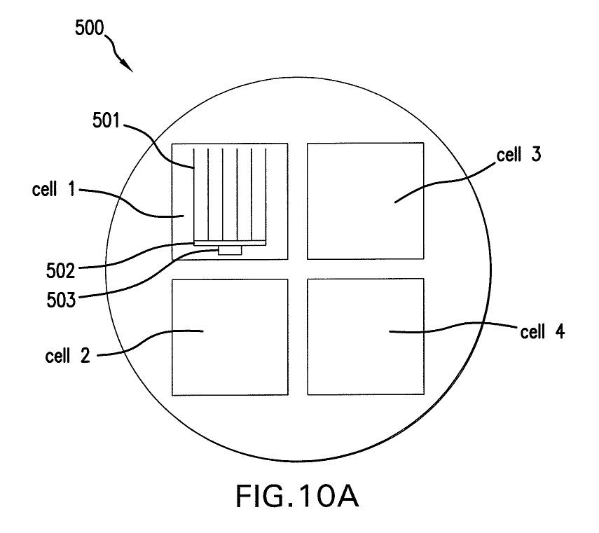

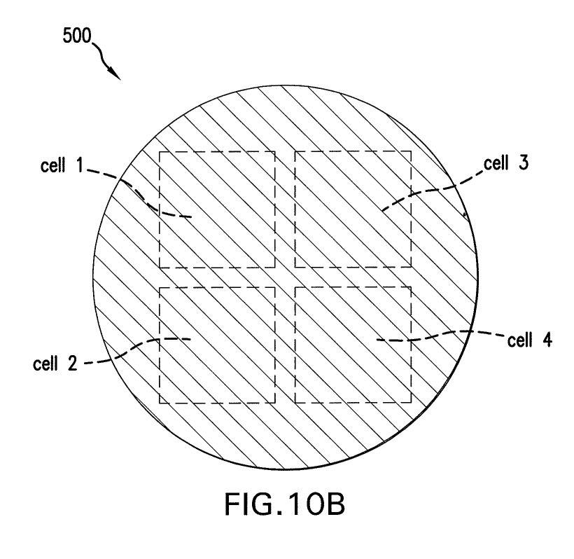

FIG. 10A is a top plan view of a wafer in which four solar cells are implemented. The depiction of four cells is for illustration for purposes only, and the present invention is not limited to any specific number of cells per wafer.

In each cell there are grid lines 501 (more particularly shown in cross-section in FIG. 9), an interconnecting bus line 502, and a contact pad 503. The geometry and number of grid and bus lines is illustrative and the present invention is not limited to the illustrated embodiment.

FIG. 10B is a bottom plan view of the wafer with four solar cells shown in FIG. 10A.

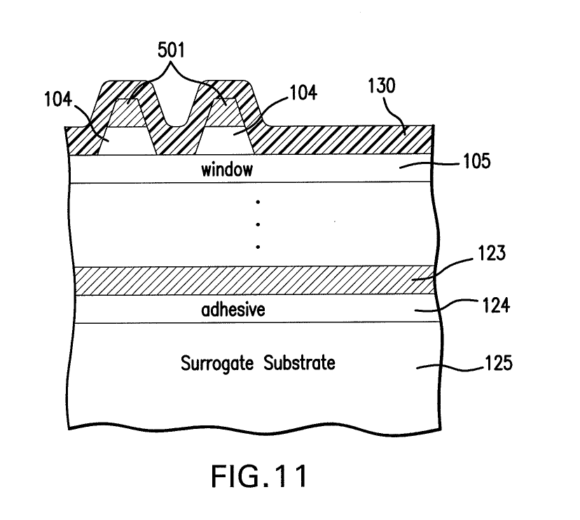

FIG. 11 is a cross-sectional view of the solar cell of FIG. 11 after the next process step in which an antireflective (ARC) dielectric coating layer 130 is applied over the entire surface of the “bottom” side of the wafer with the grid lines 501.

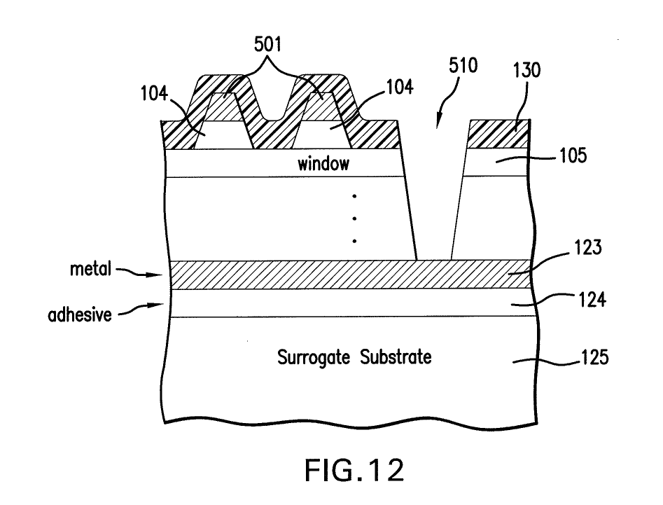

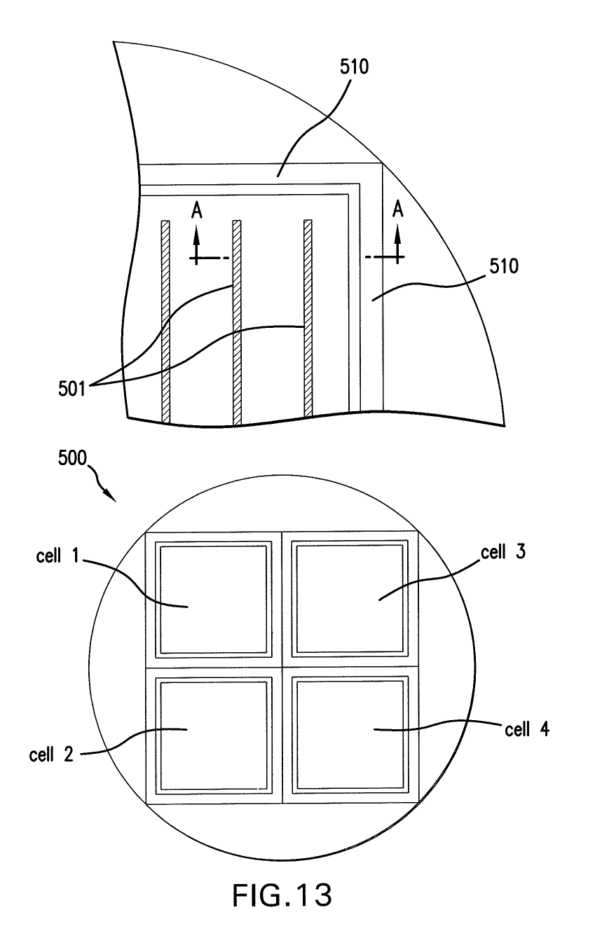

FIG. 12 is a cross-sectional view of the solar cell of FIG. 11 after the next process step according to the present invention in which a channel 510 or portion of the semiconductor structure is etched down to the metal layer 123 using phosphide and arsenide etchants defining a peripheral boundary and leaving a mesa structure which constitutes the solar cell. The cross-section depicted in FIG. 12 is that as seen from the A-A plane shown in FIG. 13.

FIG. 13 is a top plan view of the wafer of FIG. 12 depicting the channel 510 etched around the periphery of each cell using phosphide and arsenide etchants.

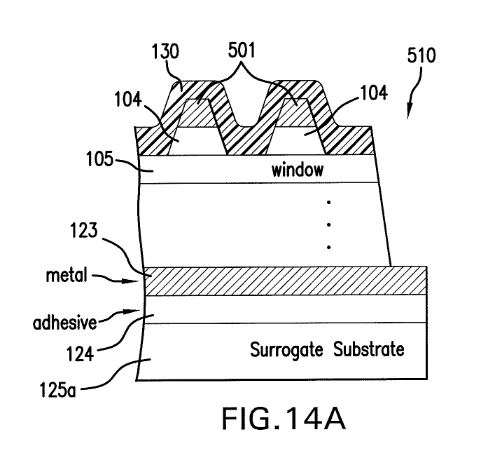

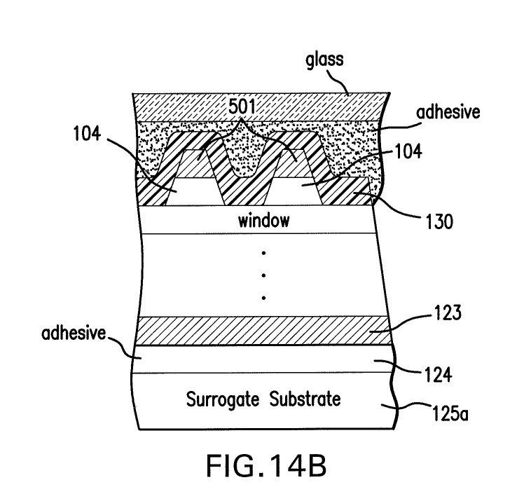

FIG. 14A is a cross-sectional view of the solar cell of FIG. 12 after the next process step in a first embodiment of the present invention in which the surrogate substrate 125 is appropriately thinned to a relatively thin layer 125a, by grinding, lapping, or etching.

FIG. 14B is a cross-sectional view of the solar cell of FIG. 14A after the next process step in a second embodiment of the present invention in which a cover glass is secured to the top of the cell by an adhesive.

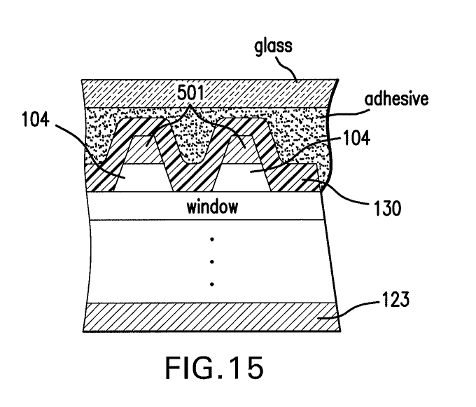

FIG. 15 is a cross-sectional view of the solar cell of FIG. 14B after the next process step in a third embodiment of the present invention in which a cover glass is secured to the top of the cell and the surrogate substrate 125 is entirely removed, leaving only the metal contact layer 123 which forms the backside contact of the solar cell. The surrogate substrate may be reused in subsequent wafer processing operations.

FIG. 16 is a graph of a doping profile in the emitter and base layers in one or more subcells of the inverted metamorphic multijunction solar cell of the present invention. The various doping profiles within the scope of the present invention, and the advantages of such doping profiles, are more particularly described in copending U.S. patent application Ser. No. 11/956,069 filed Dec. 13, 2007, herein incorporated by reference. The doping profiles depicted herein are merely illustrative, and other more complex profiles may be utilized as would be apparent to those skilled in the art without departing from the scope of the present invention.

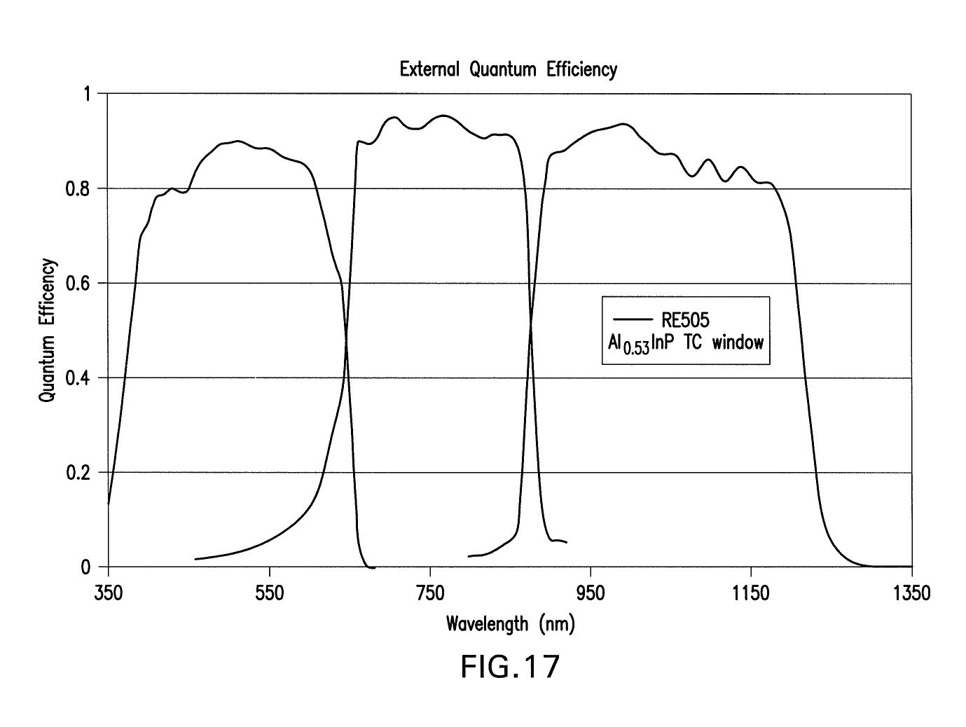

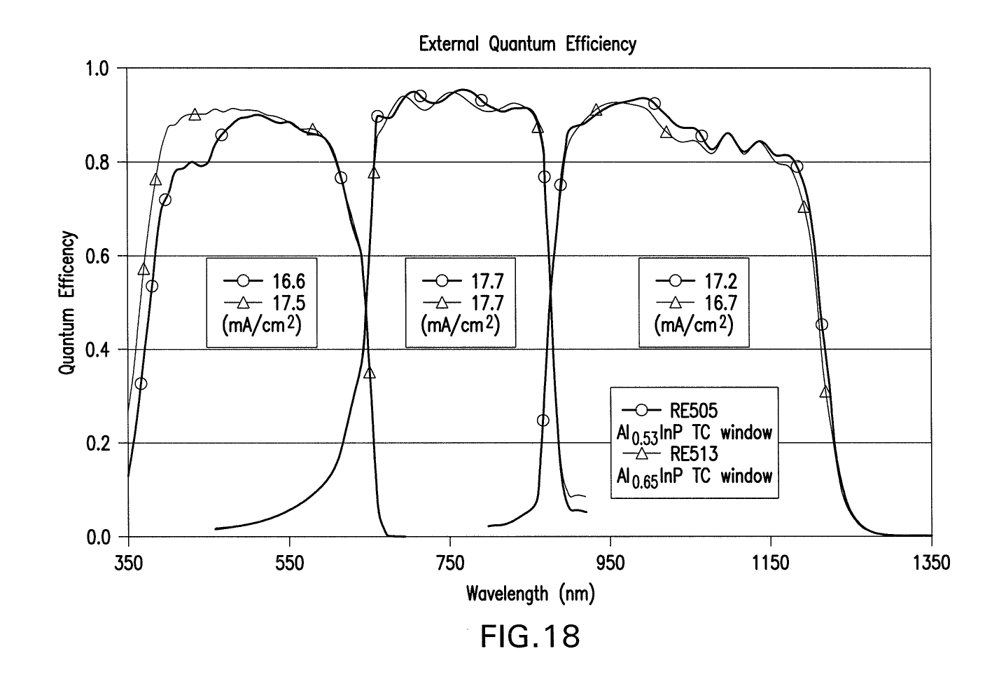

Experimental indication of the efficacy of the present invention is provided in FIGS. 17 and 18. A structure of the type shown in FIG. 17 with an Al_{0.53}InP top cell window layer 105 was grown and fabricated into 4 cm² cells as was known and used prior to the present invention. External quantum efficiency (EQE) measurements were made and the results shown in FIG. 17 indicate that the integrated current of the top subcell A was 16.6 mA/cm² the middle cell 17.7 mA/cm², and the bottom cell 17.2 mA/cm².

A cell with a Al_{0.65}InP top cell window layer was grown and fabricated, and EQE measurements made. The EQE graph for the cell with a Al_{0.65}InP top cell window layer is shown in FIG. 18 superimposed on the EQE graph of the cell depicted in FIG. 17 for comparison purposes.

The current in the device with the Al_{0.65}InP window layer was 17.5 mA/cm² in the top cell (“TC”) 17.7 mA/cm² in the middle cell, and 16.7 mA/cm² in the bottom cell. This result compares with 16.6 mA/cm² in the top cell of the device with a Al_{0.53}InP window layer, 17.7 mA/cm² in the middle cell, and 17.2 mA/cm² in the bottom cell. The overall increase in current of 0.9 mA/cm² in the top cell, where a substantial part of the photon energy is absorbed, is particularly notable and demonstrates the advantage of the use of an Al_{0.65}InP window layer according to the present invention.

It will be understood that each of the elements described above, or two or more together, also may find a useful application in other types of constructions differing from the types of constructions described above.

Although the preferred embodiment of the present invention utilizes a vertical stack of three subcells, the present invention can apply to stacks with fewer or greater number of subcells, i.e. two junction cells, four junction cells, five junction cells, etc. In the case of four or more junction cells, the use of more than one metamorphic grading interlayer may also be utilized.

In addition, although the present embodiment is configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the present invention may utilize an arrangement of one or more, or all, homojunction cells or subcells, i.e., a cell or subcell in which the p-n junction is formed between a p-type semiconductor and an n-type semiconductor both of which have the same chemical composition and the same band gap, differing only in the dopant species and types, and one or more heterojunction cells or subcells. Subcell A, with p-type and n-type InGaP is one example of a homojunction subcell. Alternatively, as more particularly described in U.S. patent application Ser. No. 12/023,772 filed Jan. 31, 2008, the present invention may utilize one or more, or all, heterojunction cells or subcells, i.e., a cell or subcell in which the p-n junction is formed between a p-type semiconductor and an n-type semiconductor having different chemical compositions of the semiconductor material in the n-type regions, and/or different band gap energies in the p-type regions, in addition to utilizing different dopant species and type in the p-type and n-type regions that form the p-n junction.

The composition of the window or BSF layers may utilize other semiconductor compounds, subject to lattice constant and band gap requirements, and may include AlInP, AlAs, AlP, AlGaInP, AlGaAsP, AlGaInAs, AlGaInPAs, GaInP, GaInAs, GaInPAs, AlGaAs, AlInAs, AlInPAs, GaAsSb, AlAsSb, GaAlAsSb, AlInSb, GalnSb, AlGaInSb, AlN, GaN, InN, GaInN, AlGaInN, GaInNAs, AlGaInNAs, ZnSSe, CdSSe, and similar materials, and still fall within the spirit of the present invention.

While the invention has been illustrated and described as embodied in a inverted metamorphic multijunction solar cell, it is not intended to be limited to the details shown, since various modifications and structural changes may be made without departing in any way from the spirit of the present invention.

Thus, while the description of this invention has focused primarily on solar cells or photovoltaic devices, persons skilled in the art know that other optoelectronic devices, such as, thermophotovoltaic (TPV) cells, photodetectors and light-emitting diodes (LEDS) are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand LEDs can also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method of forming a multijunction solar cell comprising an upper subcell, a middle subcell, and a lower subcell, the method comprising:
providing first substrate for the epitaxial growth of semiconductor material;
forming a first solar subcell on said substrate having a first band gap; said cell including a base layer and an emitter layer, and a window layer adjacent to said emitter layer and lattice mismatched thereto, having a lattice constant which differs from the lattice constant of the emitter layer by less than approximately 0.9%;
forming a second subcell over said first subcell having a second band gap smaller than said first band gap;
forming a grading interlayer over said second solar subcell, said grading interlayer having a third band gap greater than said second band gap; and
forming a third subcell over said grading interlayer having a fourth band gap smaller than said second band gap such that said third subcell is lattice mismatched with respect to said second subcell.

2. The method as defined in claim 1, wherein the window layer is composed of InAlP, with x in the range of 0.60 to 0.70.

3. The method as defined in claim 1, wherein the window layer is pseduomorphic.

4. A method as defined in claim 1, wherein the window layer is strained so that dislocations do not propogate into the cell structure.

5. A method as defined in claim 1, wherein said second solar cell is composed of a GaInP, GaInAs, GaAsSb, or GaInAsN emitter region and a GaInAs, GaAsSb, or GaInAsN base region.

6. A method as defined in claim 1, wherein said grading interlayer is composed of any of the As, P, N, Sb based III-V compound semiconductors subject to the constraints of having the in-plane lattice parameter greater or equal to that of the second solar cell and less than or equal to that of the third solar cell, and having a band gap energy grater than that of the second solar cell.

7. A method as defined in claim 5, wherein said second solar subcell is composed of InGaP emitter region and a GaAs base region.

8. A method as defined in claim 1, wherein said grading interlayer is composed of InGaGlAs.

9. A method as defined in claim 1, further comprising attaching a surrogate second substrate over said third solar cell and removing the first substrate.

10. A method of manufacturing a solar cell comprising:
providing a first semiconductor substrate;
depositing on a first substrate a sequence of layers of semiconductor material forming a solar cell including a window layer with a bandgap of more than 2.25 eV;
mounting a surrogate second substrate on top of the sequence of layers; and
removing the first substrate.

11. A method as defined in claim 10, the window layer is pseudomorphic and is composed of AlₓInP, with x in the range of 0.60 to 0.70, and has a lattice constant which differs from the adjacent solar cell by less than 0.9%.

12. The method as defined in claim 10, wherein the sequence of layers of semiconductor material forms a triple junction solar cell including top, middle and bottom solar subcells.

13. The method as defined in claim 10, wherein the mounting step includes adhering the solar cell to the surrogate substrate.

14. The method as defined in claim 10, wherein the surrogate substrate is selected from the group of sapphire, Ge, GaAs, or silicon.

15. The method as defined in claim 10, wherein the solar cell is bonded to said surrogate substrate by an adhesive.

16. The method as defined in claim 10, wherein the solar cell is eutectically bonded to the surrogate substrate.

17. The method as defined in claim 10, further comprising thinning the surrogate substrate to a predetermined thickness.

18. The method as defined in claim 10, further mounting the solar cell on a support and removing the surrogate substrate.

19. The method as defined in claim 18, wherein the support is a rigid coverglass.

20. The method as defined in claim 12, wherein said middle and bottom subcells are lattice mismatched.

21. A method as defined in claim 20, further comprising depositing a graded interlayer between said middle and bottom subcells, said interlayer having a band gap greater than the band gap of said middle subcell.

22. A method as defined in claim 23, wherein said graded interlayer is composed of any of the As, P, N, Sb based III-V compound semiconductors subject to the constraints of having the in-plane lattice parameter or equal to that of the middle subcell and less than or equal to that of the bottom subcell.

23. A method as defined in claim 21, wherein the graded interlayer is composed of (InₓGa₁₋ₓ)yAl_{1-y}As, with x and y selected such that the band gap of the interlayer remains constant at approximately 1.50 eV.

24. A method for increasing current generation in a photovoltaic cell or other optoelectronic device comprising
providing a subcell an emitter layer having a first lattice constant;
growing a lattice-mismatched window layer positioned directly adjacent to said emitter layer composed of a material, having a second lattice constant different from the first lattice constant material lattice constant and said second material lattice constant differ in material lattice constant values by at least less than approximately 1.0%, wherein said lattice mismatched window layer is fully strained window layer.

25. The method as defined in claim 24, wherein the window layer is composed of InAlₓP, with x in the range of 0.60 to 0.70.

26. The method as defined in claim 24, wherein the window layer is pseduomorphic.

27. A method as defined in claim 24, wherein the window layer is fully strained.

28. A method as defined in claim 24, wherein said window layer has a band gap of more than 2.25 eV.

29. A multijunction solar cell comprising:
a substrate;
a first solar subcell on said substrate having a first band gap;
a pseudomorphic window layer disposed over said first subcell having a bandgap greater than that of a lattice matched window layer;
a second solar subcell disposed over said first subcell and having a second band gap smaller than said first band gap;
a grading interlayer disposed over said barrier layer and having a third band gap greater than said second band gap; and
a third solar subcell disposed over said grading interlayer that is lattice mismatched with respect to said middle subcell and having a fourth band gap smaller than said third band gap.

30. A solar cell as defined in claim 29, wherein said window layer is composed of InAlₓP, where x is in the range 0.60 to 0.70.

31. A solar cell as defined in claim 29, wherein the substrate is selected from the group consisting of germanium or GaAs.

32. A solar cell as defined in claim 29, wherein said first solar subcell is composed of InGa(Al)P.

33. A solar cell as defined in claim 29, wherein said second solar subcell is composed of an GaInP, GaInAs, GaAsSb, or GaInAsN emitter region and an GaInAs, GaAsSb, or GaInAsN base region.

34. A solar cell as defined in claim 29, wherein said third solar subcell is composed of InGaAs.
